(19) United States
(12) Patent Application Publication
(10) Pub. No.: US 2025/0021013 A1
(43) Pub. Date: Jan. 16, 2025

(54) PROCESS AND DEVICE FOR CHEMICAL PROCESSING OF A SURFACE

(71) Applicant: Carl Zeiss SMT GmbH, Oberkochen (DE)

(72) Inventors: Jan Philip KRAACK, Westhausen (DE); Andreas SIEBLIST, Aalen (DE)

(21) Appl. No.: 18/901,767

(22) Filed: Sep. 30, 2024

Related U.S. Application Data
(63) Continuation of application No. PCT/EP2023/058108, filed on Mar. 29, 2023.

(30) Foreign Application Priority Data
Apr. 1, 2022 (DE) 10 2022 203 298.5

(51) Int. Cl. G03F 7/00; G03F 7/30

(52) U.S. Cl. CPC G03F 7/70316; G03F 7/30

(57) ABSTRACT

A process for chemical processing of a surface, in particular (32) of a substrate (31) of a component (MX, 117) of a projection exposure apparatus (1, 101) for semiconductor lithography. A chemical processing brought about by a reaction fluid (38) is limited to a predetermined region (36) by application of a further fluid (39) to this region (36). Also disclosed is a device (30) for chemical processing of at least one surface (32), wherein the device (30) includes a spray array with at least two spray units (34,35) for applying a fluid (38,39). A first spray unit (34) is embodied such that a first region (36) of the surface (32) is treated with a reaction fluid (38) and a second spray unit (35) is embodied such that a second region (37) of the surface (32) is treated with the further fluid (39).

### CROSS-REFERENCE TO RELATED APPLICATIONS

This is a Continuation of International Application PCT/EP2023/058108 which has an international filing date of Mar. 29, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2022 203 298.5 filed on Apr. 1, 2022.

### FIELD OF THE INVENTION

The invention relates to a process and a device for chemical processing of a surface. It relates in particular to the chemical processing of a surface of a substrate for a component of a projection exposure apparatus for semiconductor lithography.

### BACKGROUND

Such substrates may in particular be parts of optical components, such as mirrors used for imaging or illuminating a mask. For the production of layer structures on such substrates, photolithographic processes are often used, by applying a radiation-sensitive coating, such as a photoresist, to the surface to be structured and irradiating it with the aid of masks or locally applied beam writing equipment using electromagnetic radiation, and subsequently developing it. In this way, the desired structures can be created on a substrate.

The coating can be irradiated here with a wavelength in the range of around 500 nm and below. The subsequent development dissolves the exposed regions, creating the desired structure in the coating. The uniform and complete removal of the coating is highly relevant for the further operating steps, and so high demands are placed on the development rate, i.e. the amount of coating dissolved per unit time, over the substrate. The development of the coating is a heterogeneous chemical reaction which can be carried out by spraying or squirting a chemical reaction fluid onto a surface from a single spray unit, or a collection of spray units, such as an array. Here, for example, a movable spray unit can be displaced spatially in at least two dimensions relative to a surface.

In order to ensure a temporally and spatially homogeneous reaction, i.e. development of the coating, over a surface to be processed that is large relative to the extent of the spray unit of the reaction fluid, the chemical reaction fluid must be continuously replaced or renewed on the area to be processed. The disadvantage of such processes is an uncontrolled flow behavior of the reaction fluid on the surface to be processed, driven mainly by the gravitation and/or the topography of the surface to be developed, especially outside the area directly wetted by the spray unit. This causes a spatial and temporal uncertainty in the rate of development of the surface.

Application of this process for substrates of a component of a projection exposure apparatus for semiconductor lithography which, for example, have macroscopically spherical or aspherical surfaces on which microscopic free-form faces are partially superimposed, leads to an adverse reinforcement of this effect.

### SUMMARY

An object of the present invention is to provide a process and a device which mostly remove or eliminate the disadvantages described above for the prior art.

This and other objects are addressed by a process and a device having the features recited in the independent claims. The dependent claims relate to advantageous developments and variants thereof.

According to one aspect of the invention, a process for chemical processing of a surface is proposed which includes limiting a chemical reaction brought about by the reaction fluid to a predetermined region by application of a further fluid. This has the advantage that the reaction dynamics of a reaction fluid in the form, for example, of a developer can be controlled spatially with high precision. The limited region moves over the surface, and so the entire surface of the substrate can be chemically processed in a defined manner. The movement of the region over the surface can thus be used to control the temporal aspect of the chemical reaction in addition to the spatial control of the chemical reaction. All in all, a very high predictive accuracy of the reaction dynamics of the chemical processing on the surface, i.e. the development rate, can be achieved and the development of the coating can be controlled with high spatial and temporal precision.

In a first embodiment, the predetermined region can be limited by neutralizing the action of the reaction fluid. The further fluid can be applied to the surface such that two regions with different fluids form on the surface. In the contact region of the two regions, the fluids mix, thereby allowing the chemical action of the reaction fluid, such as a developer for coatings, to be neutralized. By a relative movement of the device with respect to the surface, the region treated with reaction fluid can be treated with the further fluid, thereby likewise neutralizing the chemical action of the reaction fluid.

In particular, the further fluid can be embodied as a neutralization fluid; that is, the chemical reaction of the reaction fluid, through its chemical properties, and in particular a chemical reaction induced as a result, can be prevented.

In addition, the further fluid can be embodied as a dilution fluid. The dilution fluid neutralizes the action of the reaction fluid not by preventing the chemical reaction itself, but by diluting the reaction fluid, as a result of which the chemical reaction is slowed so that it no longer has a relevant reaction rate and is thereby neutralized.

In a further embodiment of the process, the predetermined region can be limited by displacing the reaction fluid. The surface of the substrate can be treated with the further fluid so that it can limit the extent of the area treated with reaction fluid by displacement. The further fluid may have physical properties, so that displacement of the reaction fluid instead of mixing with the reaction fluid occurs even when the further fluid is applied to a region already wetted with the reaction fluid.

In particular, the further fluid may be embodied as a displacement fluid.

Furthermore, the displacement fluid may comprise dry air. This can displace the reaction fluid from the surface and can be embodied, for example, in the form of an air knife, i.e. a linear air jet.

In a further embodiment of the invention, at least one first spray unit can treat a first region of the surface with reaction fluid and at least one second spray unit can treat a second region of the surface with a further fluid.

In particular, the two areas can border one another. At the interface, the reaction rate of the reaction fluid can be reduced as explained above. A plurality of second spray units can be assigned to a first spray unit for the reaction fluid, so that the region wetted by the first spray unit can be limited by a multiplicity of regions sprayed with a further fluid. A plurality of second spray units can also be assigned to an array with a plurality of first spray units for the reaction fluid.

In addition, the second region can partially surround the first region. Depending on the design of the spray pattern of a nozzle of a second spray unit, the second region can partially surround the first. In the case of a plurality of second spray units, the individual second regions can partially surround the first region.

In particular, the second region can completely surround the first region. As a result, the extent of the first region which is wetted with reaction fluid can be completely spatially controlled.

Furthermore, the two regions can overlap. In particular in the case in which the reaction fluid, as explained above, is limited by dilution, overlapping of the regions can bring about reaction dynamics decreasing continuously toward the edge of the region, which may be advantageous for the edge of the coating.

In particular, the surface may be located on an optical element.

Furthermore, the surface may be spherical or aspherical and/or at least partially have a free-form face. The surface here may have a macroscopically spherical or aspherical shape and/or at least partially have a microscopic free-form face superimposed on it.

The process can be used as already mentioned advantageously for processing a substrate of a component of a projection exposure apparatus for semiconductor lithography. In principle, however, the process can be used for related applications from practically all areas of technology.

According to a further aspect of the invention, a device for chemically processing at least one surface is proposed, which comprises a spray array with at least two spray units for applying a fluid. The first spray unit is embodied such that a first region of the surface is treated with a reaction fluid and a second spray unit is embodied such that a second region of the surface is treated with a further fluid.

Furthermore, the device can comprise a drying unit. This can effectively prevent wetting of certain regions of the surface, especially regions that are not to be wetted. Alternatively, the drying unit can completely prevent the reaction dynamics of the reaction fluid by exsiccation, in which case initial concentration of the reaction fluid as a result of the exsiccation must be considered.

In particular, the drying unit can be embodied as an air knife. As already explained earlier on above, the air knife can be used on the one hand for drying, but also for displacement and thus limiting of regions on the surface.

In addition, the device can comprise a suction unit. This unit can be arranged within or in the direction of movement of the air knife in front of an air knife and can suction off the fluids located on the surface. The reaction fluid loses chemical reaction dynamics because of the reaction with the coating and is therefore continually renewed. As a result of the suction, a flow can form within the first region from a central point, which is treated with fresh reaction fluid, to the edge of the region. There, the reaction effect of the reaction fluid is first neutralized or attenuated and subsequently the reaction fluid is suctioned off by the suction unit. The air knife ensures that no fluid remains outside the currently processed region on the surface. Alternatively, the region in which the reaction fluid acts can also be limited only by air knives and the suction unit.

Furthermore, the device can comprise at least one sensor for detecting the topography of the surface. The sensor can be arranged such that it detects the surface before wetting of the coating and transmits the signals to an actuator of the device. The actuator can determine the parameters for the spray units from the detected signals, thereby enabling a development rate optimized for the actual topography of the surface.

### BRIEF DESCRIPTION OF THE DRAWINGS

Exemplary embodiments and variants are explained in more detail below with reference to the drawing. In the figures:

FIG. 1 shows schematically a meridional section through a projection exposure apparatus for EUV projection lithography,

FIG. 2 shows schematically a meridional section through a projection exposure apparatus for EUV projection lithography,

FIGS. 3A and 3B show schematic representations, in sectional and plan views respectively, of embodiments according to the invention, and

FIG. 4 shows a further embodiment according to the invention.

### DETAILED DESCRIPTION

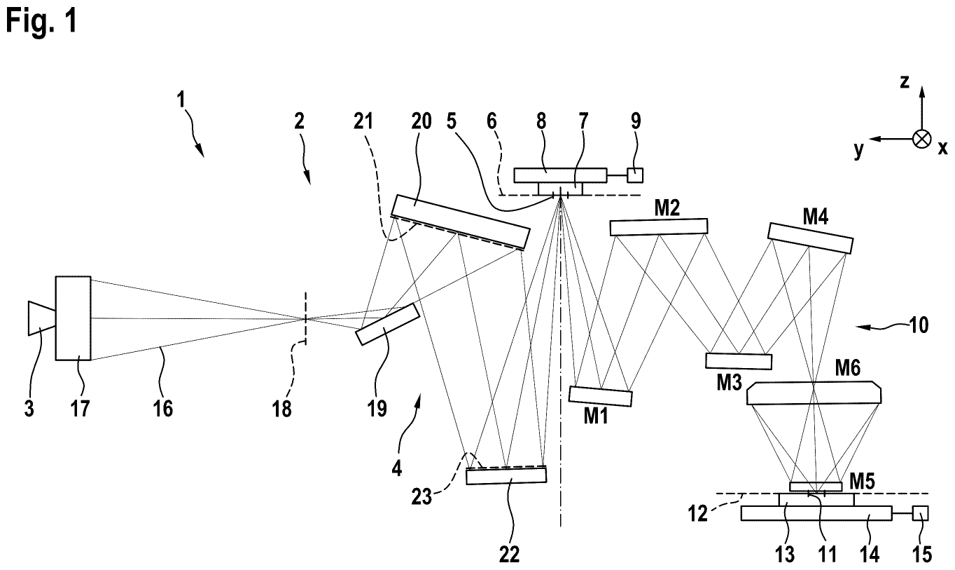

In the text below, the predominant constituents of a projection exposure apparatus 1 for microlithography are first described illustratively with reference to FIG. 1. The description here of the basic structure of the projection exposure apparatus 1 and also its constituents are not to be understood in a restrictive manner.

An embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable via a reticle displacement drive 9, in particular in a scanning direction.

In FIG. 1, a Cartesian xyz coordinate system is drawn in for elucidation. The x-direction is perpendicular to the drawing plane. The y-direction is horizontal and the z-direction is vertical. The scanning direction in FIG. 1 runs along the y-direction. The z-direction is perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 can be displaced via a wafer displacement drive 15, in particular along the y-direction. The displacement on the one hand of the reticle 7 via the reticle displacement drive 9 and on the other hand of the wafer 13 via the wafer displacement drive 15 can be carried out synchronously with each other.

The radiation source 3 is an EUV radiation source. The radiation source 3 emits, in particular, EUV radiation 16, which is also referred to below as useful radiation, illumination radiation or illumination light. In particular, the useful radiation has a wavelength in the range between 5 nm and 30 nm. The radiation source 3 can be a plasma source, such as a laser-produced plasma (LPP) source or a gas discharge-produced plasma (DPP) source. It can also be a synchrotron-based radiation source. The radiation source 3 can be a free electron laser (FEL).

The illumination radiation 16 emerging from the radiation source 3 is focused by a collector 17. The collector 17 can be a collector having one or having a plurality of ellipsoidal and/or hyperboloid reflection surfaces. The illumination radiation 16 can be incident on the at least one reflection surface of the collector 17 with grazing incidence (GI), i.e., at angles of incidence of greater than 45° relative to the direction of the normal to the mirror surface, or with normal incidence (NI), i.e., at angles of incidence of less than 45°. The optical surface of the collector 17 may be structured and/or coated on the one hand to optimize its reflectivity for the useful radiation and on the other hand to suppress extraneous light.

After the collector 17, the illumination radiation 16 propagates through an intermediate focus in an intermediate focal plane 18. The intermediate focal plane 18 may represent a separation between a radiation source module, comprising the radiation source 3 and the collector 17, and the illumination optical unit 4.

The illumination optical unit 4 comprises a deflection mirror 19 and, downstream thereof in the beam path, a first facet mirror 20. The deflection mirror 19 can be a flat deflection mirror or alternatively a mirror with a bundle-influencing effect beyond the pure deflection effect. Alternatively or additionally, the deflection mirror 19 may be implemented as a spectral filter, which separates a useful light wavelength of the illumination radiation 16 from extraneous light having a wavelength that deviates therefrom. If the first facet mirror 20 is arranged in a plane of the illumination optical unit 4 which is optically conjugate to the object plane 6 as a field plane, it is also referred to as a field facet mirror. The first facet mirror 20 comprises a multiplicity of individual first facets 21, which are also referred to below as field facets. FIG. 1 illustrates only some of these facets 21 by way of example.

The first facets 21 may be implemented as macroscopic facets, in particular as rectangular facets or as facets with an arc-shaped or part-circle-shaped edge contour. The first facets 21 can be implemented as flat facets or alternatively as convex or concave curved facets.

As is known, for example, from DE 10 2008 009 600 A1, the first facets 21 themselves can each also be composed of a multiplicity of individual mirrors, in particular a multiplicity of micromirrors. The first facet mirror 20 may be embodied in particular as a microelectromechanical system (MEMS system). For details, reference is made to DE 10 2008 009 600 A1.

Between the collector 17 and the deflection mirror 19, the illumination radiation 16 runs horizontally, i.e. along the y-direction.

In the beam path of the illumination optical unit 4, a second facet mirror 22 is disposed downstream of the first facet mirror 20. Provided the second facet mirror 22 is arranged in a pupil plane of the illumination optical unit 4, it is also referred to as a pupil facet mirror. The second facet mirror 22 may also be spaced apart from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may also be macroscopic facets, which may be circularly, rectangularly or else hexagonally delimited, for example, or alternatively may be facets composed of micromirrors. In this regard, reference is again made to DE 10 2008 009 600 A1.

The second facets 23 may have flat or alternatively convex or concave curved reflection surfaces.

The illumination optical unit 4 thus forms a double-faceted system. This basic principle is also referred to as a fly's eye integrator.

It can be advantageous to arrange the second facet mirror 22 not exactly in a plane which is optically conjugate to a pupil plane of the projection optical unit 10. In particular, the pupil facet mirror 22 may be arranged with a tilt relative to a pupil plane of the projection optical unit 10, as described, for example, in DE 10 2017 220 586 A1.

The individual first facets 21 are imaged into the object field 5 using the second facet mirror 22. The second facet mirror 22 is the last bundle-shaping mirror or else actually the last mirror for the illumination radiation 16 in the beam path ahead of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or else, alternatively, two or more mirrors, which are arranged in succession in the beam path of the illumination optical unit 4. The transfer optical unit can in particular comprise one or two normal-incidence mirrors (NI mirrors) and/or one or two grazing-incidence mirrors (GI mirrors).

In the implementation shown in FIG. 1, the illumination optical unit 4 has exactly three mirrors downstream of the collector 17, specifically the deflection mirror 19, the field facet mirror 20 and the pupil facet mirror 22.

In a further implementation of the illumination optical unit 4, the deflecting mirror 19 can also be omitted, so that the illumination optical unit 4 can then have exactly two mirrors after the collector 17, specifically the first facet mirror 20 and the second facet mirror 22.

The imaging of the first facets 21 into the object plane 6 with the second facets 23 or using the second facets 23 and a transfer optical unit is generally only an approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or a different number of mirrors Mi are also possible. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and which can also be greater than 0.6 and which, for example, can be 0.7 or 0.75.

Reflection surfaces of the mirrors Mi can be in the form of free-form faces without an axis of rotational symmetry. Alternatively, the reflection surfaces of the mirrors Mi can be designed as aspherical faces with exactly one axis of rotational symmetry of the reflection surface shape. Just like the mirrors of the illumination optical unit 4, the mirrors Mi may comprise highly reflective coatings for the illumination radiation 16. These coatings may be in the form of multi-layer coatings, in particular with alternating layers of molybdenum and silicon.

The projection optical unit 10 has a large object-image offset in the y-direction between a y-coordinate of a center of the object field 5 and a y-coordinate of the center of the image field 11. In the y-direction, this object-image offset can be of approximately the same size as a z-distance between the object plane 6 and the image plane 12.

The projection optical unit 10 may in particular have an anamorphic form. In particular, it has different imaging scales βx, βy in the x- and y-directions. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 may be the same or may be different depending on the design of the projection optical unit 10. Examples of projection optical units with different numbers of such intermediate images in the x- and y-directions are known from US 2018/0074303 A1.

One of the pupil facets 23 in each case is assigned to exactly one of the field facets 21, in each case to form an illumination channel for illuminating the object field 5. In particular, this can produce illumination according to the Köhler principle. The far field is deconstructed into a multiplicity of object fields 5 using the field facets 21. The field facets 21 create a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%. Field uniformity can be achieved by superimposing different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets that guide light. This intensity distribution is also referred to as illumination setting.

A likewise preferred pupil uniformity in the region of portions of an illumination pupil of the illumination optical unit 4 that are illuminated in a defined way can be achieved by a redistribution of the illumination channels.

Further aspects and details of the illumination of the object field 5 and in particular of the entrance pupil of the projection optical unit 10 are described below.

The projection optical unit 10 may have a homocentric entrance pupil in particular. The latter can be accessible. It can also be inaccessible.

The entrance pupil of the projection optical unit 10 generally cannot be illuminated exactly with the pupil facet mirror 22. The aperture rays often do not intersect at a single point in the event of imaging by the projection optical unit 10 that telecentrically images the center of the pupil facet mirror 22 onto the wafer 13. However, it is possible to find an area in which the spacing of the aperture rays, determined in pairs, is minimal. This area represents the entrance pupil or an area in real space that is conjugate thereto. In particular, this area exhibits a finite curvature.

It may be the case that the projection optical unit 10 has different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different positions of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged with a tilt in relation to the object plane 6. The first facet mirror 20 is arranged with a tilt in relation to an arrangement plane defined by the deflection mirror 19.

The first facet mirror 20 is arranged with a tilt in relation to an arrangement plane defined by the second facet mirror 22.

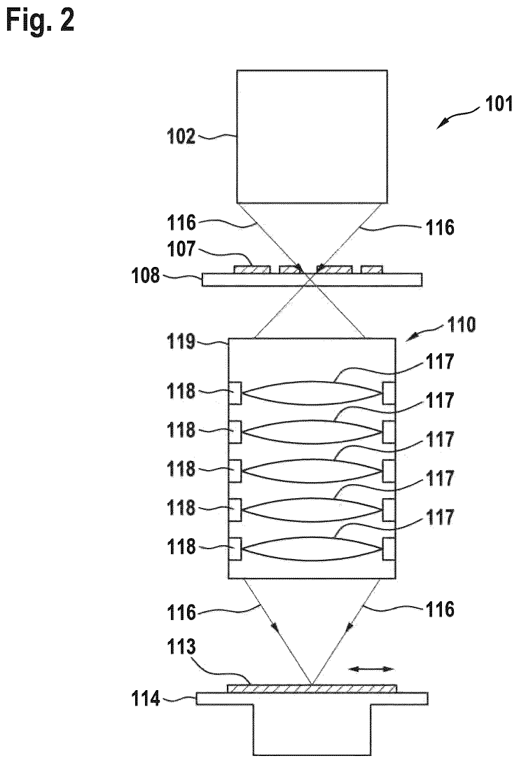

FIG. 2 schematically shows a meridional section through a further projection exposure apparatus 101 for DUV projection lithography, in which embodiments of the invention can likewise be used.

The setup of the projection exposure apparatus 101 and the principle of the imaging are comparable with the construction and procedure described in FIG. 1. Identical or comparable components are denoted by a reference sign increased by 100 with respect to FIG. 1, i.e., the reference signs in FIG. 2 start at 101.

In contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as useful light, in the range from 100 nm to 300 nm, in particular of 193 nm. The projection exposure apparatus 101 in this case essentially comprises an illumination system 102, a reticle holder 108 for receiving and exactly positioning a reticle 107 provided with a structure, the reticle determining the later structures on a wafer 113, a wafer holder 114 for holding, moving, and exactly positioning this wafer 113, and a projection lens 110, with multiple optical elements 117, which are held with mounts 118 in a lens housing 119 of the projection lens 110.

The illumination system 102 provides DUV radiation 116 required for the imaging of the reticle 107 on the wafer 113. A laser, a plasma source or the like can be used as the source of this radiation 116. The radiation 116 is shaped in the illumination system 102 with optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optical unit 110 with the lens housing 119 fundamentally does not differ from the structure described in FIG. 1 and is therefore not described further.

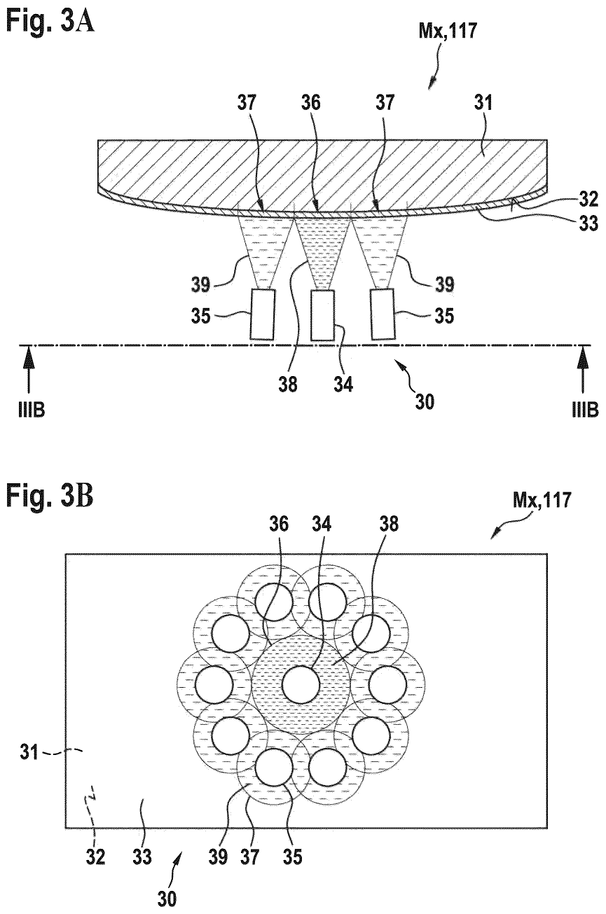

FIG. 3A shows a sectional representation of an embodiment of the invention, in which an optical element Mx, 117, as explained for example in FIG. 1 and FIG. 2, is represented illustratively in a device 30 according to this embodiment of the invention. The optical element Mx, 117 comprises a substrate 31 having a surface 32 on which a coating 33 to be structured is formed. Instead of the optical element Mx, 177, of course, other bodies or elements for photolithographic structuring can also be processed in the device 30. The device 30 comprises, in the embodiment represented in FIG. 3A, a first spray unit 34, which wets a first region 36 of the surface 32 with a reaction fluid in the form of a developer 38. As a result, the coating 33, which is exposed by a lithographic process, for example, is developed. The constancy of the development rate is highly relevant to the quality of the structuring of the coating 33, and so the reaction dynamics of the developer 38 should be controlled spatially and temporally homogeneously on the surface 32.

Second spray units 35 are arranged on each of the two sides of the first spray unit 34. The second spray units 35 each wet second regions 37, which limit the first region 36, with a further fluid in the form of a dilution fluid 39. The dilution of the developer 38 stops or slows the chemical reaction of the developer 38 such that it no longer causes a significant development rate, thereby limiting the chemical reaction spatially to the first region 36. Alternatively or in addition, a neutralization fluid can also be used as a further fluid, thereby likewise limiting the chemical reaction to the first region 36. The substrate 31 is moved on an unillustrated positioning device, such as a robot arm, relative to the stationary device 30, so that the first region 36 moves over the surface 32, thereby developing the entire coating 33 of the surface 32. The distance of the spray units 34, 35 to the surface 32 has an influence on the chemical reaction, as do the arrangement of the coating 33 of the substrate 31 with respect to gravity, the surface topography of the coating 33, and other parameters. The amount and concentration, i.e. the reactivity, of the developer 38 and the amount of the dilution fluid 39 are only some parameters of the spray units 34, 35 that contribute to homogeneous development of the coating 33. The relative movement between substrate 31 and device 30 advantageously comprises six degrees of freedom, allowing the inclination of the treated regions during the process over the surface 32 to be adapted as well, thus ensuring an at least approximately constant flow behavior of the fluids 38, 39 on the surface 32. Alternatively, the device 30 can also be moved relative to the substrate 31 or a combination of both methods can be selected, so that, for example, the device 30 performs linear movements relative to the substrate 31, while the substrate additionally rotates about at least one axis.

FIG. 3B shows a plan view of the surface 32 of the optical element Mx, 117. The device 30 comprises, in addition to the centrally arranged first spray unit 34, in the embodiment shown in FIG. 3B, ten second spray units 35, which are arranged rotationally symmetrically around the first spray unit 34. The regions 36, 37 wetted by the spray patterns of the individual spray units 34, 35 are shown in FIG. 3B as circles on the surface 32 of the substrate 31. In addition to a circular spray pattern, almost any form of spray patterns, such as full-conical, flat-jet and hollow-cone profiles, can be employed. In addition, apart from by spraying, wetting can also be brought about by misting or squirting. The first region 36, wetted with developer 38, is limited in all directions by the second regions 37, wetted by the second spray units 35 with dilution fluid 39. This ensures a clear spatial effect of the developer 38. The amount of fluid, the temperature, the pressure ahead of the spray unit 34, 35 and the concentration of the developer 38 are just some of the parameters which can be controlled for setting the predetermined reaction dynamics of the developer 38 on the coating 33, as already explained earlier on above.

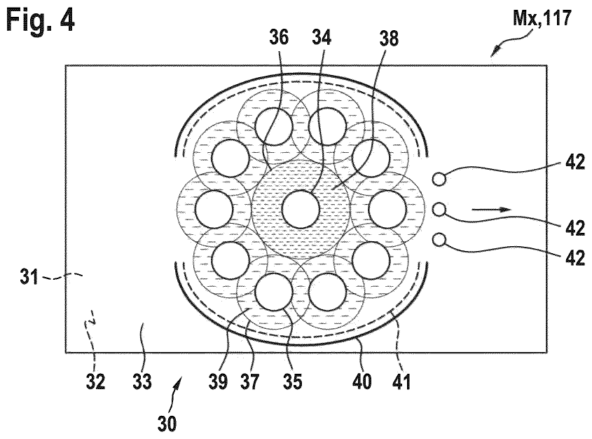

FIG. 4 shows another embodiment of the invention, where the optical element Mx, 117 is again represented in a plan view. In addition to the spray units 34, 35 already explained in FIG. 3B, this device 30 comprises a drying unit embodied as an air knife 40. The air knife 40 is a linear air jet, which is embodied such that each fluid 38, 39 is limited in its extent on the surface 32 by the air jet. This means that regions of the coating 33 can be protected from contact with the developer 38 and/or the dilution fluid 39. In addition, the air knife 40 can also remove fluids 38, 39 in its direction of movement from the surface 32, by the air knife 40 displacing them and so driving them in front of it. Optionally, in turn, in the direction of movement of the air knife 40, a suction unit 41 may be arranged in front of the air knife 40, and is represented with the dashed lines in FIG. 4. This unit suctions off the fluid 38, 39 which is located on the surface 32 and which is composed of developer 38 and dilution fluid 39, with the air knife 40 again pushing the fluid 38, 39 in front of itself; as a result, a dry surface 32 outside the air knife 40 can be ensured. Furthermore, the device 30 comprises, illustratively, three sensors 42, which are arranged in front of the spray units 34, 35 in the direction of movement, which is indicated by an arrow, and which detect the precise surface topography of the coating 33. The detected signals are transmitted via signal lines to an unillustrated actuator of the device 30. The actuator determines the parameters of the spray units 34, 35 in order to ensure a homogeneous development rate over the entire surface 32.

As an alternative to the illustrated embodiment, the air knife 40 and also the suction unit 41 may also be arranged in the device 30 such that the first region 36 wetted by the developer 38 is limited thereby in order to control the spatial action of the developer 38 instead of a dilution by a further fluid 39.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Device
31 Substrate
32 Surface
33 Coating
34 First spray unit
35 Second spray unit
36 First region
37 Second region
38 Reaction fluid
39 Further fluid
40 Air knife
41 Suction unit
42 Sensor
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors

What is claimed is:

1. A process for chemically processing a surface, comprising:
applying a chemical reaction fluid to the surface, and
limiting the chemical processing brought about by the chemical reaction fluid to a predetermined region by applying a further fluid to the predetermined region, wherein both the chemical reaction fluid and the further fluid are liquids.

2. The process as claimed in claim 1,
wherein said limiting comprises:
limiting the predetermined region by neutralizing the chemical processing brought about by the chemical reaction fluid.

3. The process as claimed in claim 1,
wherein the further fluid comprises a neutralization fluid.

4. The process as claimed in claim 1,
wherein the further fluid comprises a dilution fluid.

5. The process as claimed in claim 1,
wherein said limiting comprises:
limiting the predetermined region by displacing the chemical reaction fluid.

6. The process as claimed in claim 1,
wherein the further fluid comprises a displacement fluid.

7. The process as claimed in claim 1,
wherein
said applying of the chemical reaction fluid comprises treating a first region of the surface via at least one first spray unit with the chemical reaction fluid, and
said applying of the further fluid comprises treating a second region of the surface via at least one second spray unit with the further fluid.

8. The process as claimed in claim 7,
wherein the first region and the second region border one another.

9. The process as claimed in claim 7,
wherein the second region partially surrounds the first region.

10. The process as claimed in claim 7,
wherein the second region completely surrounds the first region.

11. The process as claimed in claim 7,
wherein the first region and the second region overlap.

12. The process as claimed in claim 1,
wherein the surface is located on an optical element.

13. The process as claimed in claim 1,
wherein the surface is spherical or aspherical and/or has at least partially a freeform face.

14. The process as claimed in claim 1,
wherein the surface is located on a substrate of a component of a projection exposure apparatus for semiconductor lithography.

15. A device for chemically processing at least one surface, the device comprising:
a spray array with at least two spray units configured to apply at least one fluid,
wherein a first of the spray units is configured to treat a first region of the surface with a reaction fluid and a second of the spray units is configured to treat a second region of the surface with a further fluid, and
at least one sensor configured to detect a topography of the surface.

16. The device as claimed in claim 15, further comprising:
a drying unit.

17. The device as claimed in claim 16,
wherein the drying unit comprises an air knife.

18. The device as claimed in claim 15, further comprising:
a suction unit.
